(19) United States
(12) Patent Application Publication
(10) Pub. No.: US 2025/0253210 A1
(43) Pub. Date: Aug. 7, 2025

(54) JET IMPINGEMENT COOLING FOR HIGH POWER SEMICONDUCTOR DEVICES USING MONOLITHIC MICROSTRUCTURES

(71) Applicant: SEMICONDUCTOR COMPONENTS INDUSTRIES, LLC, Scottsdale, AZ (US)

(72) Inventors: Amith JAIN, Tempe, AZ (US); John MOOKKEN, Scottsdale, AZ (US)

(73) Assignee: SEMICONDUCTOR COMPONENTS INDUSTRIES, LLC, Scottsdale, AZ (US)

(21) Appl. No.: 18/434,625

(22) Filed: Feb. 6, 2024

(51) Int. Cl. H01L 23/473; H01L 25/07

(52) U.S. Cl. CPC H01L 23/4735; H01L 25/072

(57) ABSTRACT

A jet impingement cooling assembly for semiconductor devices includes an inlet chamber to receive an inlet fluid flow, a jet plate having at least one jet nozzle, and positioned to direct the inlet fluid flow from the inlet chamber through the at least one jet nozzle to provide an impinging fluid flow, and a heat exchange base to receive at least one semiconductor device with a frontside facing away from the inlet chamber and a backside facing the jet plate. The jet impingement cooling assembly includes an impingement layer positioned between the at least one jet nozzle and the backside of the at least one semiconductor device to receive the impinging fluid flow, the impingement layer having impingement surface structures formed thereon, and an outlet chamber positioned to receive the impinging fluid flow after the impinging fluid flow impinges on the impingement layer and the impingement surface structures.

### TECHNICAL FIELD

This description relates to cooling techniques for semiconductor devices.

### BACKGROUND

High power semiconductor devices, during operation, generate heat that may be harmful to the devices themselves, or to nearby components. For example, excess heat may cause an abrupt device breakdown, or may contribute to shortening of a device lifetime.

To mitigate such potential difficulties, liquid cooling systems may be used to cool high power semiconductor devices. For example, a pump may be used to direct a flow of water or other suitable cooling liquid to high-heat areas, to thereby facilitate heat transfer from the high-heat areas to the cooling liquid.

### SUMMARY

According to one general aspect, a jet impingement cooling assembly for semiconductor devices may include an inlet chamber configured to receive an inlet fluid flow, a jet plate having at least one jet nozzle formed therein and coupled to the inlet chamber, and positioned to direct the inlet fluid flow from the inlet chamber through the at least one jet nozzle to provide an impinging fluid flow, and a heat exchange base configured to receive at least one semiconductor device with a frontside facing away from the inlet chamber and a backside facing the jet plate. The jet impingement cooling assembly may further include an impingement layer positioned between the at least one jet nozzle and the backside of the at least one semiconductor device to receive the impinging fluid flow, the impingement layer having impingement surface structures formed thereon, and an outlet chamber positioned to receive the impinging fluid flow after the impinging fluid flow impinges on the impingement layer and the impingement surface structures, to thereby provide an outlet fluid flow.

According to another general aspect, an impingement layer for jet impingement cooling of at least one semiconductor device may include a mounting surface disposed to receive the at least one semiconductor device, and an impingement surface that is opposed to the mounting surface and having impingement surface structures formed thereon, wherein the impingement layer, when disposed within a heat exchange base, has the impingement surface disposed to receive an impinging fluid flow from at least one jet nozzle of a jet plate, to thereby provide the jet impingement cooling of the at least one semiconductor device.

According to another general aspect, a method of making an impingement layer for a jet impingement cooling assembly for semiconductor devices may include forming impingement surface structures on an impingement surface of the impingement layer.

The details of one or more implementations are set forth in the accompanying drawings and the description below. Other features will be apparent from the description and drawings, and from the claims.

### BRIEF DESCRIPTION OF THE DRAWINGS

FIG. 1 is an example cross-sectional side view of a jet impingement cooling assembly for high power semiconductor devices using monolithic microstructures.

FIG. 2 is a flowchart illustrating an example manufacturing process for making a jet impingement cooling assembly, in accordance with example embodiments described herein.

FIG. 3 is an exploded view of a first example embodiment of an impingement layer with monolithic microstructures of FIG. 1.

FIG. 4 is a bottom view of an example impingement layer of FIG. 1, illustrating example impingement surface structures.

FIG. 5 is a top view of an example cooling jacket.

FIG. 6 is a bottom view of an example impingement layer of FIG. 1 that is compatible with the example implementation of FIG. 5.

FIG. 7 is a top view of an assembled version of the impingement layer of FIG. 5 and the cooling jacket of FIG. 6.

FIG. 8 is a side view of an alternate example implementation.

FIG. 9 is a side view of an alternate example implementation of a semiconductor power module that may be used in the jet assembly cooling assembly of FIG. 1.

### DETAILED DESCRIPTION

As described in detail below, embodiments include a heat exchange assembly for performing jet impingement cooling of semiconductor power modules. The heat exchange assembly includes an impingement layer with a mounting surface on which the semiconductor power modules are disposed. The impingement layer further includes an impingement surface that is opposed to the mounting surface, and on which a jet impingement fluid impinges during cooling operations. The impingement surface includes impingement surface structures formed thereon, which increase a surface area of the impingement surface and thereby improve heat dissipation provided by the jet impingement cooling.

Jet impingement cooling using described techniques may thus be used to improve a thermal performance of the semiconductor power modules being cooled, including, e.g., improving an output power in traction inverters of electric vehicles. Performance improvements over existing or conventional techniques may be obtained with minimal additional processing and no additional space requirements. Described techniques may be used in the context of many different contexts and constructions of various types of jet impingement cooling assemblies.

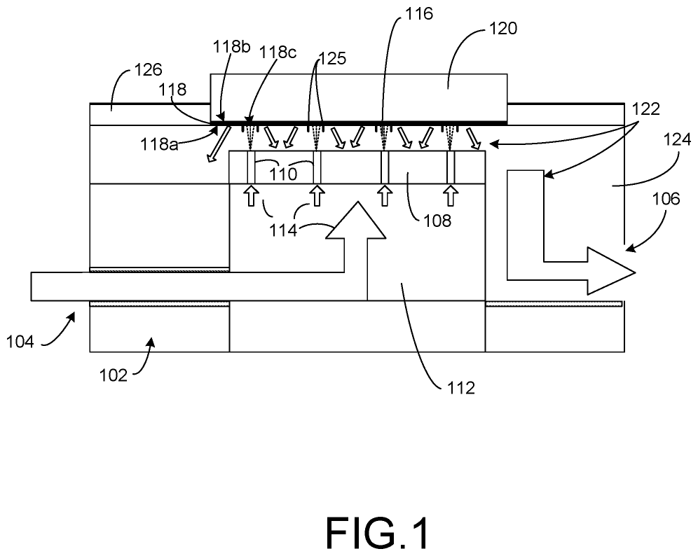

FIG. 1 is an example cross-sectional side view of a jet impingement cooling assembly for high power semiconductor devices using monolithic microstructures. In FIG. 1, a heat exchange base 102 (which may be referred to, or include, a water jacket or cooling jacket) includes an inlet connection 104, which may be in fluid contact with a fluid pump (not illustrated in FIG. 1) to receive an inlet fluid flow 114. The heat exchange base 102 also includes an outlet connection 106, which may be part of a fluid loop that returns an outlet fluid flow 122 to the fluid pump. That is, the heat exchange base 102 for jet impingement cooling may be only part of a fluid loop used within a larger setting (e.g., within an automobile or other vehicle, and possibly including one or more additional jet impingement cooling assemblies) to provide fluid-based heat dissipation to multiple components.

A jet plate 108 may be positioned within the heat exchange base 102. Multiple jet nozzles 110 may be formed within the jet plate 108, in various configurations. The jet plate 108 may be integrated with, sealed to, or otherwise attached to an inlet chamber 112. For example, the jet plate 108 and the inlet chamber 112 may be formed integrally as a single structure (e.g., using injection molding or 3D printing techniques), or the jet plate 108 may be attached to the inlet chamber 112 using an adhesive. In some examples, the jet plate 108 may be mounted to the inlet chamber 112 and interchangeable with other jet plates having different configurations.

The inlet fluid flow 114, such as a water flow, may be maintained through the inlet connection 104 and into the inlet chamber 112. As shown in FIG. 1, the inlet fluid flow 114 is directed through the jet nozzles 110.

The jet nozzle 110 provides a vent, gap, or opening through which the pressurized inlet fluid flow 114, after flowing through the inlet connection 104, is forced, thereby providing an impinging fluid flow 116 that impinges upon an impingement layer 118 to dissipate heat generated by a semiconductor power module 120. The semiconductor power module 120 may include at least one semiconductor device with a frontside facing away from the inlet chamber 112 and a backside facing the impingement layer 118 and the jet plate 108.

The impinging fluid flow 116, after impinging on the impingement layer 118, is dispersed as an outlet fluid flow 122 within an outlet chamber 124. The outlet fluid flow 122 may thus proceed through the outlet connection 106, as referenced above.

As also referenced above, the jet nozzles 110 may be sized, spaced, and positioned in any suitable or desired fashion on the jet plate 108. For example, the jet nozzles 110 may be formed as a circular or rectangular array. Individual ones of the jet nozzles 110 may be any desired and suitable shape, such as, e.g., circular, or ellipsoidal.

The jet nozzles 110 may be formed within the jet plate 108, as shown, or may be attached or otherwise positioned at least partially on the jet plate 108, e.g., using a separate jet nozzle structure, which itself may have a desired and suitable width, length, and height. Thus, the jet plate 108 forms a sealed connection with the inlet chamber 112, so that the inlet fluid flow 114 received by way of the inlet connection 104 is forced through the jet nozzles 110 to provide the impinging fluid flow 116 and thus the outlet fluid flow 122.

The impingement layer 118 may be a metal layer, such as copper, as described in various examples below. The impingement layer 118 is illustrated as including an impingement surface 118a, upon which the impingement fluid flow 116 impinges, as well as an opposed mounting surface 118b, on which the semiconductor power module 120 is mounted.

As referenced above, and illustrated in FIG. 1, the impingement surface 118a may include impingement surface structures 125. The impingement surface structures 125 may represent, for example, monolithic microstructures formed on or in the impingement layer 118 on a side of the impingement surface 118a. The impingement surface structures 125 increase a total surface area of the impingement surface 118a, and thereby increase a quantity and efficiency of heat dissipation with respect to heat generated by operations of the semiconductor power module 120.

The impingement surface structures 125 may be straightforward and inexpensive to include in the jet impingement cooling system of FIG. 1. For example, the impingement surface structures 125 may be formed using etching processes, such as laser etching, or may be selectively plated onto the impingement surface 118a. The impingement layer 118 with the impingement surface structures 125 may be 3D printed, or any suitable additive manufacturing technique(s) may be used. The impingement surface structures 125 may be formed in virtually any desired number, position(s), pattern/distribution, or size(s) that may be desired, various examples of which are described and illustrated, below.

The impingement surface structures 125 may provide improved heat dissipation with few or no detrimental effects on a pressure drop present in the jet impingement cooling system of FIG. 1. That is, as the fluid flow 114/122 proceeds through the jet impingement cooling system of FIG. 1, including circulating through other heat exchange base(s) and fluid pump(s) not pictured in FIG. 1, a pressure drop may exist between any two given points that undesirably decreases a velocity, and thus efficacy, of heat dissipation effects of the jet impingement fluid flow 116.

Efforts to improve a desired cooling effect of jet impingement cooling system(s) often involve a tradeoff with pressure drops within or among the system(s). For example, extending a length of the inlet chamber 112 to provide more jet nozzles 110 and/or to cool more heat sources (e.g., semiconductor devices) may increase a pressure drop across the inlet chamber 112.

In other examples, it may be possible to offset such pressure drops using other conventional techniques, such as by adding a larger or more expensive fluid pump. However, in addition to adding cost, such approaches may have other negative effects, such as increasing a velocity of the impingement fluid flow 116 beyond a level needed for heat dissipation, which may lead to erosion of the impingement surface 118a.

The impingement surface structures 125, as referenced above, may contribute little or nothing to such pressure drops. Moreover, the impingement surface structures 125 may be numbered, structured, sized, and positioned to minimize any pressure drops that may occur.

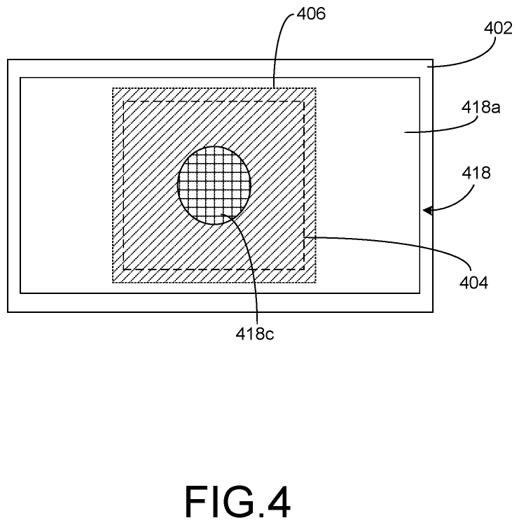

As described in more detail below, e.g., with respect to FIGS. 4, 6, and 8, an open zone 118c may be provided on the impingement surface 118a, directly opposed to, or across from, a corresponding jet nozzle 110. The open zone 118c enables direct impingement of impingement fluid flow 116 on the impingement surface 118a, followed by dispersal of the outlet fluid flow 122 over, across and/or through the impingement structures 125.

A size of the open zone 118c may be determined, for example, based on a diameter or other parameter of a corresponding jet nozzle 110. Characteristics of the impingement structures 125 may also be determined as a function(s) of the jet nozzle(s) 110.

Characteristics of the impingement structures 125 may also be determined based on a size or other characteristics of the semiconductor power module 120. For example, FIG. 1 illustrates a single semiconductor power module 120 being cooled by a plurality of jet nozzles 110. In other examples, however, multiple semiconductor power modules may be positioned on the mounting surface 118b, with one or more corresponding jet nozzles 110 and impingement structures 125 positioned accordingly for optimized cooling of the semiconductor power modules.

Although the impingement layer 118 is illustrated as a singular layer with the semiconductor power module 120 mounted thereon, it will be appreciated that the impingement layer 118 may include two or more layers/materials, and/or that the semiconductor power module 120 may be mounted indirectly on (e.g., may not be directly or immediately adjacent to) the mounting surface 118b of the impingement layer 118. For example, the impingement layer 118 may be a metal layer joined to a dielectric layer, and the semiconductor power module 120 may be mounted (directly or indirectly) on the dielectric layer (e.g., ceramic), such as when the impingement layer 118 is formed as part of an insulated metal substrate (IMS), also referred to as a Direct Bonded Metal (DBM), e.g., a direct bonded copper (DBC) substrate.

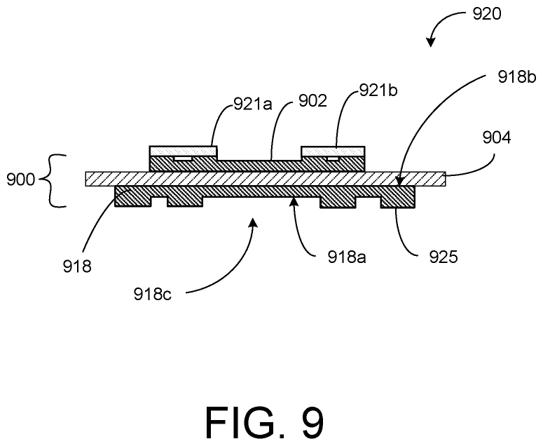

Additionally, in some implementations, e.g., as illustrated and described with respect to FIG. 9, an integrated semiconductor power module may be used that includes an IMS, e.g., DBC, substrate with an active metal (e.g., copper) trace on an active side (e.g., uppermost in FIG. 1), a non-conducting ceramic layer on which the active metal trace is provided, and a metal (e.g., copper) on the non-active (e.g., lower in FIG. 1) side of the non-conducting ceramic layer. In such embodiments, the convective heat transfer improving impingement structures 125 may be provided in the non-active side, while any desired or suitable semiconductor power device(s) may be mounted to, and connected by, the active side.

The impingement layer 118 and/or the semiconductor power module 120 may be mounted to the heat exchange base 102 by a mounting member 126. For example, the mounting member 126 may represent a structure or structural element that encases and/or supports the impingement layer 118 and/or the semiconductor power module 120. For example, the mounting member 126 may be integrally formed with the heat exchange base 102, or may be sealed to the heat exchange base 102, or may be otherwise joined to the heat exchange base 102.

It will be appreciated that specific components and aspects of the assembly of FIG. 1 are illustrated only for the ease and clarity of explanation, and are not intended to be limiting. For example, the various components are not drawn to scale, and no requirement is implied with respect to relative sizes or dimensions of any of the illustrated components. For example, the inlet chamber 112 may have a length that is much greater than its height, or may otherwise have different relative dimensions than those shown in the example of FIG. 1. Additionally, other components may be included that are not shown in FIG. 1, such as a chamber divider between the inlet chamber 112 and the outlet chamber 124.

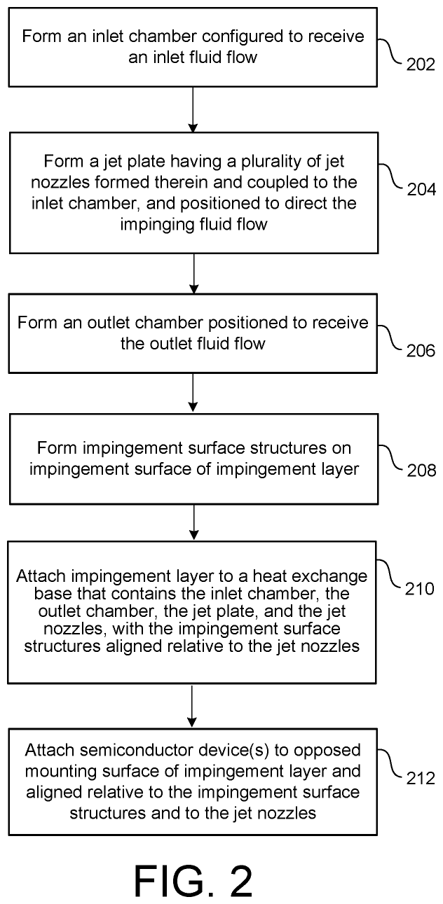

FIG. 2 is a flowchart illustrating an example manufacturing process for making a jet impingement cooling assembly, in accordance with example embodiments described herein. In FIG. 2, operations 202-212 are illustrated as separate, ordered, sequential operations. However, it will be appreciated that in various example manufacturing processes, the operations 202-212 may be performed in a different order than that shown and/or may be executed partially or completely in parallel. Moreover, additional or alternative operations may be included, and/or one or more operations may be omitted.

In the example of FIG. 2, the inlet chamber 112 configured to receive the inlet fluid flow 114 may be formed (202). The jet plate 108 having a plurality of jet nozzles 110 formed therein and coupled to the inlet chamber 112 may be formed, and positioned to direct the impinging fluid flow 116 (204). The outlet chamber 124 may be formed that is positioned to receive the outlet fluid flow 122 (206).

Impingement surface structures 125 may be formed on the impingement surface 118a of the impingement layer 118 (208). As described above, the impingement surface structures 125 may be formed using a variety of low-cost manufacturing techniques, including, e.g., laser etching, selective plating, or 3D printing techniques.

Any suitable size, shape, number, density, and arrangement of the impingement surface structures 125 may be selected, perhaps based on other characteristics of the cooling assembly. For example, the impingement surface structures 125 may be circular or rectangular in shape. The impingement surface structures 125 may have a constant diameter or thickness, or may be thinner at a portion(s) of the impingement surface structures 125 that are distal from the impingement surface 118a. Example implementations of the impingement surface structures 125 may have a height in the range of, e.g., 0.1-1 micron, although other suitable heights may be chosen, as well.

The impingement layer 118 may be attached to a heat exchange base 102 that contains the inlet chamber 112, the outlet chamber 124, the jet plate 108, and the jet nozzles 110, with the impingement surface structures 125 aligned relative to the jet nozzles 110 (210). For example, the mounting member 126 may be used. As described herein, the impingement surface structures 125 may be aligned relative to the jet nozzles, so that the open zone 118c is positioned to be directly opposed from the jet nozzles 110.

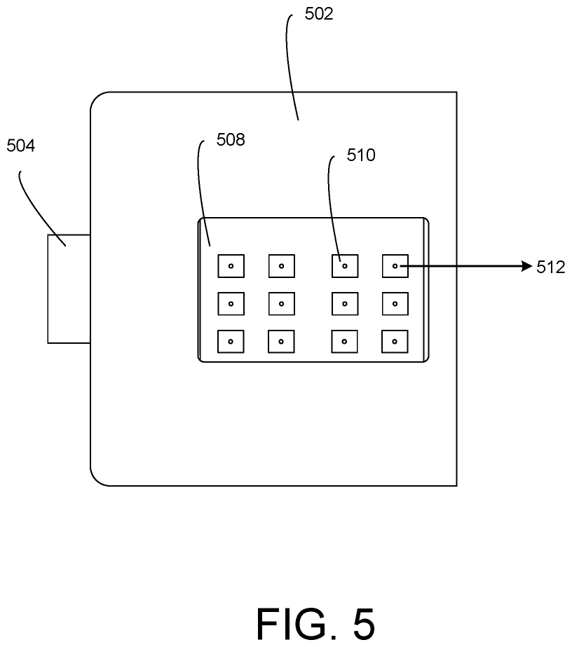

An overall arrangement of the impingement surface structures 125 may also be aligned relative to the jet nozzles 110. For example, as shown in FIGS. 5-7, the impingement surface structures 125 may be arranged as an array of concentric circles, with the open zone 118c defining the center of the concentric circles.

A semiconductor device(s) may be attached to the opposed mounting surface 118b of the impingement layer 118 and aligned relative to the impingement surface structures and to the jet nozzles 110 (212). For example, the semiconductor power module 120 may be attached, directly or indirectly, to the impingement layer 118. In some examples, a center of the semiconductor power module 120 may be aligned relative to a single one of the jet nozzles 110, e.g., with a center of the semiconductor power module 120 positioned over the open zone 118c and/or one of the jet nozzles 110. In other examples, a center of the semiconductor power module 120 may be aligned relative to two or more of the jet nozzles 110, such as when a center of the semiconductor power module 120 is aligned over a centroid of two or more of the jet nozzles.

As noted, the operations 202-212 of FIG. 2 may be performed in a different order than that shown. Further, two or more of the operations 202-212 may be combined, while a single one of the operations 202-212 may be performed in two or more stages. For example, the semiconductor device(s) of operation 212 may be attached to the impingement layer 118 prior to the operation 210 of attaching the impingement layer to the heat exchange base.

The various components may thus be formed integrally to some extent, or may be formed separately and then attached using any suitable technique, including, e.g., soldering, or using any suitable adhesive or other sealant. The various configurations described herein, including any desired variation in size, position, or number of the jet nozzles 110, and corresponding aspects of the impingement surface structures 125, may be manufactured inexpensively and quickly.

Thus, the devices and methods of FIGS. 1 and 2 provide, with desired levels of velocity and pressure, a cooling liquid with high accuracy and/or precision to identified hotspots of semiconductor power modules. For example, described jet impingement cooling assembly embodiments provide direct contact of a cooling fluid to a backside (e.g., the impingement surface 118a) of a substrate (e.g., direct bonded copper (DBC) substrate (e.g., a substrate including a dielectric disposed between a pair of metal layers for traces and/or bonding)) being cooled, with desired implementations of the impingement surface structures 125 disposed thereon.

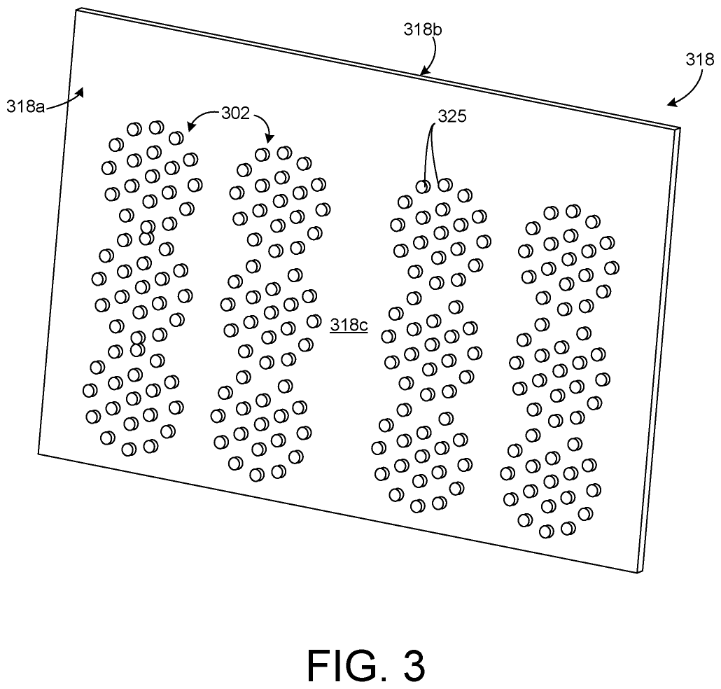

FIG. 3 is an exploded view of a first example embodiment of the impingement layer 118 with monolithic microstructures providing impingement surface structures 125 of FIG. 1. In the example of FIG. 3, an impingement layer 318 includes an impingement surface 318a with impingement surface structures 325 formed thereon. An opposed mounting surface 318b of the impingement layer 318 is opposite the impingement surface 318a.

In the example of FIG. 3, the various impingement surface structures 325 are formed in a circular array(s) 302 of concentric circles of impingement surface structures 325. More specifically, in the example, a total of twelve circular arrays 302 are illustrated.

The construction of FIG. 3 may be used to provide impingement cooling for one or more semiconductor devices mounted on the mounting surface 318b. That is, as may be understood from FIGS. 1 and 2, the impingement layer 318 may be positioned above the jet nozzles 110 of FIG. 1 with the impingement surface structures 325 facing the jet nozzles 110, and with one or more semiconductor devices, corresponding to the semiconductor power module 120 of FIG. 1, providing on the mounting surface 318b.

For example, a single semiconductor device or module may be centered on the mounting surface 318b and may have a size that extends to or beyond a perimeter of the twelve circular arrays 302. In such scenarios, a center portion of the impingement layer 318 may provide an open zone 318c, analogous to the open zone(s) 118c of FIG. 1.

In other examples, two separate semiconductor devices or modules may each be centered with respect to two corresponding subgroups of six each of the circular arrays 302, or with respect to four subgroups of three circular arrays 302 each. In still other examples, it is possible to provide twelve separate semiconductor devices on the mounting surface 318b, with each such device positioned over a corresponding one of the circular arrays 302. In some of the preceding examples, a corresponding open zone may not be required or provided.

FIG. 4 is a bottom view of an example impingement layer of FIG. 1, illustrating example impingement surface structures characteristics. In the example of FIG. 4, an impingement layer 418 includes an impingement surface 418a. A dielectric layer 402 is provided on (e.g., bonded to) the impingement layer 418, e.g., on a mounting surface that is opposed to the impingement surface 418a and not visible in FIG. 4. For example, as shown in FIG. 9, the structure of FIG. 4 may be part of a DBC substrate.

Further in FIG. 4, a device area 404 illustrates an example area of a semiconductor device (also not visible in FIG. 4) that may be provided on the dielectric layer 402, consistent with the examples of FIGS. 1 and 2. A surface structure area 406 represents an example area that may be filled with the type of impingement surface structures 125, 325 described above with respect to FIGS. 1-3. An open zone 418c illustrates an example area for the type of open zones 118c, 318c described above with respect to FIGS. 1-3.

Thus, FIG. 4 illustrates an example in which the surface structure area 406 extends beyond a perimeter of the device area 404. As also shown, the device area is centered on a center of the open zone 418c, and a remaining area of the impingement surface 418a is not provided with any impingement surface structures.

Providing the surface structure area 406 as extending beyond the heat source area 404 may help to ensure that a benefit of included impingement surface structures will be provided for an entirety of the heat source. At the same time, the surface structure area 406 may be limited from covering an entirety of an area of the impingement surface 418a, e.g., due to diminishing returns in providing improved heat dissipation with respect to heat from the heat source.

As referenced with respect to FIG. 1, providing the open zone 418c prevents direct fluid impingement on any of the impingement surface structures and maximizes a heat dissipation benefit of the direct fluid impingement. The example of FIG. 4 illustrates a square heat source shape, but any suitable or available heat source shape may be used, and a corresponding shape of the surface structure area 406 may be chosen accordingly.

FIG. 5 is a top view of an example cooling jacket 502. As may be understood from the description of FIG. 1, the cooling jacket 502, e.g., a polymer cooling jacket, provides an example of a heat exchange base with an inlet 504, a jet plate 508, and jet nozzles 510. As may also be understood from FIG. 1, an inlet chamber, not visible in FIG. 5, may receive an inlet fluid flow from the inlet 504, which may then be forced through the jet nozzles 510 as described herein.

In FIG. 5, the jet nozzles 510 are illustrated as four groups of three, or twelve total instances of the jet nozzles 510. Each of the jet nozzles 510 is circular in shape, with a diameter 512 that is referred to herein as nozzle diameter dn.

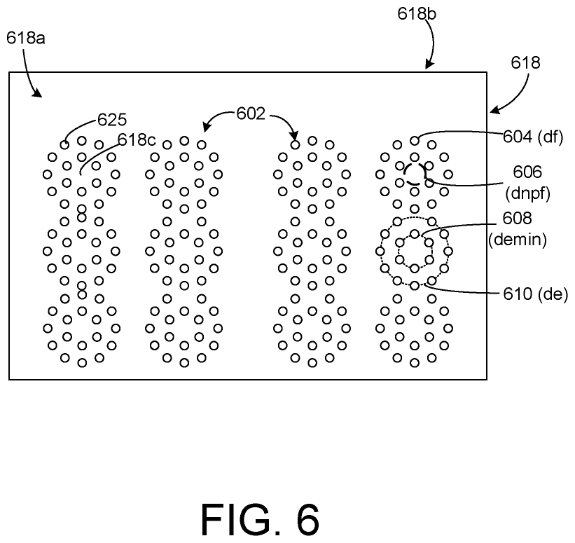

FIG. 6 is a bottom view of an example impingement layer of FIG. 1 that is compatible with the example implementation of FIG. 5. In the example of FIG. 6, an impingement layer 618 includes an impingement surface 618a with impingement surface structures 625 formed thereon. An opposed mounting surface 618b of the impingement layer 618 is opposite the impingement surface 618a.

In the example of FIG. 6, similar to FIG. 3 and compatible with FIG. 5, the various impingement surface structures 625 are formed in a circular array(s) 302 of concentric circles of impingement surface structures 625. More specifically, in the example, a total of twelve circular arrays 602 are illustrated. Each of the circular arrays 602 defines and includes an open zone 618c.

The construction of FIG. 6 may be used to provide impingement cooling for one or more semiconductor devices mounted on the mounting surface 618b, as described above. That is, the impingement layer 618 may be positioned above the jet nozzles 510 of FIG. 5 with the impingement surface structures 625 facing the jet nozzles 510, and with one or more semiconductor devices, corresponding to the semiconductor power module 120 of FIG. 1, providing on the mounting surface 618b.

In the example of FIG. 6, the impingement surface structures 625 are illustrated as cylindrical structures of constant diameter, and may be referred to herein as pinfins. As already described, many other constructions of the impingement surface structures 625 may be used, as well.

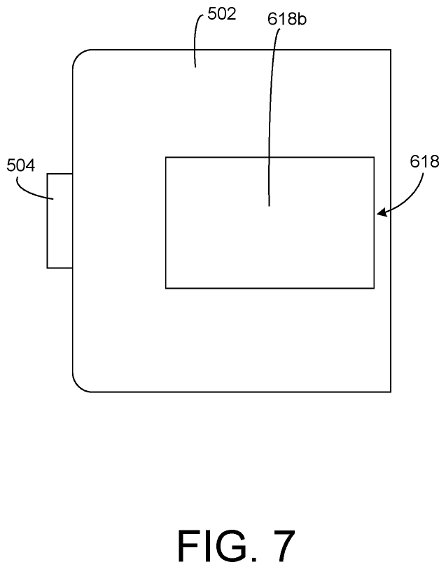

FIG. 7 is a top view of an assembled version of the impingement layer of FIG. 5 and the cooling jacket of FIG. 6. As just referenced, FIG. 7 illustrates that a mounting surface 618b may be provided and available for mounting a desired semiconductor device(s) thereon. FIG. 7 further illustrates that the impingement surface 618a may be provided with each of the circular arrays 602 being aligned with a corresponding one of the jet nozzles 510 of FIG. 5. For example, twelve corresponding semiconductor devices may be positioned on the mounting surface 618b, with device centers being positioned above corresponding ones of the open zones 618c, which are themselves each positioned over corresponding ones of the jet nozzles 510. In other words, a center of each impingement surface structure array 602 may be linearly spaced from a center of a corresponding jet nozzle of the jet nozzles 510.

FIG. 6 illustrates a number of design parameters that may be used to optimize desired cooling effects. For example, a pinfin diameter 604 for an individual pinfin or impingement surface structure 625 may be referred to as pinfin diameter df. A diameter for the open zone 618c may be referred to as open zone diameter 606, or dnpf. An inner or minimum array diameter 608 may be referred to as demin. An outer array diameter 610 may be referred to as outer array diameter de.

In example implementations, some or all of the parameters df, dnpf, demin, and de may be based on the nozzle diameter 512 (dn) of FIG. 5. For example, (dnpf) may be defined to be at least twice the nozzle diameter (dn). The minimum surface enhancement diameter (demin) may be defined to be at least three times the nozzle diameter (dn).

Many other parameterizations of the various example implementations are possible. For example, a nozzle area (An) may be defined for the jet nozzles 510, and a heat source area, analogous to the heat source area 404 of FIG. 4, may be defined as (Ahs). Then, coverage areas of the various impingement surface structures 625 (pinfins), analogous to the surface structure area 406 of FIG. 4, may be defined for various usage scenarios.

For example, for scenarios with a single jet nozzle under a heat source, a pinfin coverage area may be defined as being at least [0.5 (Ahs)]-[3 (An)]. For scenarios with multiple jet nozzles under a heat source, a pinfin coverage area may be defined as being at least [0.5 (Ahs)]-[3 (Number of jet nozzles per heat source)(An)].

It will be appreciated that the above parameterizations are merely examples, and are not limiting of the various ways in which implementations may be constructed. For example, with respect to a number or density of impingement surface structures such as the impingement surface structures 125 of FIG. 1, 325 of FIG. 3, or 625 of FIG. 6, it will be appreciated that a minimal or sufficient number of such structures may be added to achieve a desired cooling effect, while minimizing an associated pressure drop that might be caused by the impingement surface structures 125/325/625. In other words, greater pressure drop tolerance for a given application may imply a correspondingly greater number of impingement surface structures within a given area and/or over a greater area of an impingement surface.

At the same time, a density of impingement surface structures 125/325/625 may be influenced by a degree of tolerance of potential clogging effects. For example, spacing between individual ones of the impingement surface structures 125/325/625 may be based on a diameter of particles expected to pass therethrough (e.g., 1 mm or 2 mm in diameter).

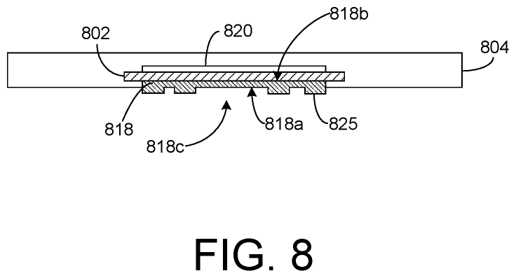

FIG. 8 is a side view of an alternate example implementation. In the example of FIG. 8, an impingement layer 818 includes an impingement surface 818a with impingement surface structures 825 formed thereon. An opposed mounting surface 818b of the impingement layer 818 is opposite the impingement surface 818a, and an open zone 818c is formed at a center of the impingement surface structures 825.

In the example of FIG. 8, the impingement layer 818, a dielectric layer 802, and a semiconductor power module 820 (or other heat source) are all at least partially embedded in an insulating material 804. For example, the embodiment of FIG. 8 may be used in a printed circuit board (PCB) context. The insulating material 804 may include pre-preg, which refers to a reinforcing fabric pre-impregnated with resin, such as epoxy, or FR4 material(s), which refers to, e.g., a flame retardant fiberglass/epoxy material.

FIG. 9 is a side view of an alternate example implementation of a semiconductor power module 920 that may be used in the jet assembly cooling assembly of FIG. 1. In FIG. 9, an integrated semiconductor power module 920 includes an IMS substrate 900, such as a DBC substrate, which includes an active metal trace 902 on an active side of the DBC substrate 900. As shown, the active metal trace 902 provides for mounting and connection of one or more semiconductor power devices, illustrated in FIG. 9 as a semiconductor power device 921a and a semiconductor power device 921b. The semiconductor power devices 921a, 921b may represent, for example, specific devices, such as insulated gate bipolar transistor (IGBT) devices, metal oxide semiconductor field effect transistor (MOSFET) devices, various types of Silicon Carbide (SiC) devices, and/or various other associated or included devices, including, for example, controllers or drivers.

The IMS substrate 900 further includes a non-conducting ceramic layer 904 on which the active metal trace 902 is provided. A metal layer 918 on a non-active side of the non-conducting ceramic layer 904, opposed to the active side of the non-conducting ceramic layer 904, may be provided with convective heat transfer improving impingement structures 925, as shown. In other words, the non-active metal layer 918 of FIG. 9 may include, e.g., may represent an example implementation of, the types of impingement layers described herein.

In FIG. 9, similar to, e.g., FIGS. 1, 3, 5, and 8, the metal layer 918 provides an impingement layer that includes an impingement surface 918a with the impingement surface structures 925 formed thereon. An opposed mounting surface 918b of the non-active metal layer 918 is opposite the impingement surface 918a, and an open zone 918c is formed at a center of the impingement surface structures 925.

It will be appreciated that all of the preceding examples are non-limiting, and many variations may be implemented. For example, a profile on a jet plate top surface may be parallel to a backside surface of a semiconductor power module being cooled, or may have a sloped surface, to produce either accelerating or decelerating fluid flow. In some examples, inlet connections and outlet connections may be located on opposed sides of a heat exchange base (e.g., to define a substantially linear fluid flow), while other example implementations may provide inlet and outlet connections adjacent to one another on a single wall of a heat exchange base, or on adjacent sidewalls of a heat exchange base.

In specific examples, the described jet impingement cooling assembly may be used for cooling in the context of automobile or other engine applications, including electric vehicles. Such applications often have high power requirements within high-heat environments, while also meeting safety mandates. In other implementations, described techniques can be used in, e.g., wind turbine electronics, rail, and industrial drives.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A jet impingement cooling assembly for semiconductor devices, comprising:
an inlet chamber configured to receive an inlet fluid flow;
a jet plate having at least one jet nozzle formed therein and coupled to the inlet chamber, and positioned to direct the inlet fluid flow from the inlet chamber through the at least one jet nozzle to provide an impinging fluid flow;
a heat exchange base configured to receive at least one semiconductor device with a frontside facing away from the inlet chamber and a backside facing the jet plate;
an impingement layer positioned between the at least one jet nozzle and the backside of the at least one semiconductor device to receive the impinging fluid flow, the impingement layer having impingement surface structures formed thereon; and
an outlet chamber positioned to receive the impinging fluid flow after the impinging fluid flow impinges on the impingement layer and the impingement surface structures, to thereby provide an outlet fluid flow.

2. The jet impingement cooling assembly for semiconductor devices of claim 1, wherein the impingement surface structures form at least one impingement surface structure array.

3. The jet impingement cooling assembly for semiconductor devices of claim 2, wherein a center of the at least one impingement surface structure array is linearly spaced from a center of the at least one jet nozzle.

4. The jet impingement cooling assembly for semiconductor devices of claim 2, wherein the at least one impingement surface structure array includes an open zone in which no impingement surface structure is included, and a center of the open zone is aligned with a center of the at least one impingement surface structure array.

5. The jet impingement cooling assembly for semiconductor devices of claim 4, wherein the open zone has an open zone diameter that is at least twice a nozzle diameter of the at least one jet nozzle.

6. The jet impingement cooling assembly for semiconductor devices of claim 2, wherein the at least one impingement surface structure array includes at least two concentric circles of impingement surface structures.

7. The jet impingement cooling assembly for semiconductor devices of claim 1, wherein the at least one semiconductor device has a device area, and the impingement surface structures have a surface structure area that extends beyond the device area.

8. The jet impingement cooling assembly for semiconductor devices of claim 7, wherein the surface structure area does not extend to a perimeter of the impingement layer.

9. The jet impingement cooling assembly for semiconductor devices of claim 7, wherein the surface structure area has a surface structure diameter that is at least three times a nozzle diameter of the at least one jet nozzle.

10. The jet impingement cooling assembly for semiconductor devices of claim 1, wherein the impingement layer and the at least one semiconductor device are at least partially embedded in an insulating material.

11. The jet impingement cooling assembly for semiconductor devices of claim 1, further comprising:
an integrated semiconductor power module that includes an insulated metal substrate (IMS), wherein the IMS substrate includes an active metal layer to which the at least one semiconductor device is connected, a non-conducting layer on which the active metal layer is mounted, and a non-active metal layer that includes the impingement layer attached to the non-conducting layer on a side opposed to the active metal layer.

12. The jet impingement cooling assembly for semiconductor devices of claim 11, wherein the IMS includes a Direct Bonded Copper (DBC) substrate, and the active metal layer and the non-active metal layer include copper.

13. An impingement layer assembly for jet impingement cooling of at least one semiconductor device, comprising:
a mounting surface disposed to receive the at least one semiconductor device; and
an impingement surface that is opposed to the mounting surface and having impingement surface structures formed thereon,
wherein the impingement layer, when disposed within a heat exchange base, has the impingement surface disposed to receive an impinging fluid flow from at least one jet nozzle of a jet plate, to thereby provide the jet impingement cooling of the at least one semiconductor device.

14. The impingement layer assembly of claim 13, wherein the impingement surface structures form at least one impingement surface structure array.

15. The impingement layer assembly of claim 14, wherein a center of the at least one impingement surface structure array is linearly spaced from a center of the at least one jet nozzle.

16. The impingement layer assembly of claim 14, wherein the at least one impingement surface structure array includes an open zone in which no impingement surface structure is included, and a center of the open zone is aligned with a center of the at least one impingement surface structure array.

17. The impingement layer assembly of claim 14, wherein the at least one impingement surface structure array includes at least two concentric circles of impingement surface structures.

18. The impingement layer assembly of claim 13, wherein the at least one semiconductor device has a device area, and the impingement surface structures have a surface structure area that extends beyond the device area.

19. The impingement layer assembly of claim 13, wherein the impingement layer and the at least one semiconductor device are at least partially embedded in an insulating material.

20. The impingement layer assembly of claim 13, further comprising:
an integrated semiconductor power module that includes an insulated metal substrate (IMS), wherein the IMS substrate includes an active metal layer to which the at least one semiconductor device is connected, a non-conducting layer on which the active metal layer is mounted, and a non-active metal layer that includes the impingement layer attached to the non-conducting layer on a side opposed to the active metal layer.

21. A method of making an impingement layer assembly for a jet impingement cooling assembly for semiconductor devices, comprising:
forming impingement surface structures on an impingement surface of an impingement layer.

22. The method of claim 21, further comprising:
etching the impingement surface structures onto the impingement surface.

23. The method of claim 21, further comprising:
forming at least one impingement surface structure array that includes the impingement surface structures.

24. The method of claim 21, further comprising:
forming the impingement surface structures in alignment with at least one semiconductor device mounted on a mounting surface of the impingement layer that is opposed to the impingement surface, and aligned so that during disposing of the impingement layer within a heat exchange base causes the impingement surface to be disposed to receive an impinging fluid flow from at least one jet nozzle of a jet plate, to thereby provide jet impingement cooling of the at least one semiconductor device.

25. The method of claim 21, further comprising:
forming an integrated semiconductor power module that includes an insulated metal substrate (IMS), wherein the IMS substrate includes an active metal layer to which at least one semiconductor device is connected, a non-conducting layer on which the active metal layer is mounted, and a non-active metal layer that includes the impingement layer attached to the non-conducting layer on a side opposed to the active metal layer.
